(19) United States
(12) Patent Application Publication
(10) Pub. No.: US 2010/0257430 A1
(43) Pub. Date: Oct. 7, 2010

(54) STORAGE DEVICE AND METHOD FOR EXTENDING LIFETIME OF STORAGE DEVICE

(76) Inventor: Ming-Cheng Chen, Changhua County (TW)

Correspondence Address: NORTH AMERICA INTELLECTUAL PROPERTY CORPORATION, P.O. BOX 506, MERRIFIELD, VA, 22116, US

(21) Appl. No.: 12/617,675

(22) Filed: Nov. 12, 2009

(30) Foreign Application Priority Data
Apr. 1, 2009 (TW) 098110855

(51) Int. Cl. H03M 13/05; G06F 11/10

(52) U.S. Cl. 714/773; 714/763; 714/E11.034

(57) ABSTRACT

The present invention provides a storage device and a method for extending lifetime of storage devices. The storage device comprises: at least a non-volatile memory unit, at least an error correction code (ECC) engine, and a control unit. The non-volatile memory unit comprises a plurality of blocks, and the blocks comprise a plurality of pages, respectively. The ECC engine is coupled to the non-volatile memory unit, and for detecting and correcting errors for the non-volatile memory unit. The control unit is coupled to the non-volatile memory unit and the ECC engine, and for selectively label a specific block in the non-volatile memory unit as an abnormal block according to an error detecting result of the ECC engine.

### BACKGROUND OF THE INVENTION

1. Field of the Invention

The present invention relates to a storage device and a related method, and more particularly, to a storage device that is capable of extending lifetime and a method that is capable of extending lifetime of a storage device.

2. Description of the Prior Art

In general, in a conventional storage device having at least a NAND type flash memory, if a block in the NAND memory unit has page program fail or block erase fail, the conventional storage device will label the block as an abnormal block and copy data in the block to another normal block. Thus, the conventional storage device usually does not have long lifetime.

### SUMMARY OF THE INVENTION

It is therefore one of the objectives of the present invention to provide a storage device that is capable of extending lifetime and a method that is capable of extending lifetime of a storage device, so as to solve the above problem.

In accordance with an embodiment of the present invention, a storage device is disclosed. The storage device comprises: at least a non-volatile memory unit, at least an error correction code (ECC) engine, and a control unit. The non-volatile memory unit comprises a plurality of blocks, and the blocks comprising a plurality of pages, respectively. The ECC engine is coupled to the non-volatile memory unit, and utilized for detecting and correcting errors for the non-volatile memory unit. The control unit is coupled to the non-volatile memory unit and the ECC engine, and utilized for selectively labeling a specific block in the non-volatile memory unit as an abnormal block according to an error detecting result of the ECC engine.

In accordance with an embodiment of the present invention, a method for extending lifetime of a storage device is disclosed. The storage device comprises at least a non-volatile memory unit and at least an ECC engine, and the non-volatile memory unit comprises a plurality of blocks, and the blocks respectively comprise a plurality of pages. The method comprises: utilizing the ECC engine to detect and correct errors for the non-volatile memory unit; and selectively labeling a specific block in the non-volatile memory unit as an abnormal block according to an error detecting result of the ECC engine.

Briefly summarized, with regard to the conventional storage device having at least a NAND type flash memory, when a block in the NAND memory unit has page program fail or block erase fail, the conventional storage device will label the block as an abnormal block without a further check. However, the storage device and related method disclosed by the present invention are not like the conventional storage device and related method, and thus the storage device disclosed by the present invention is capable of extending lifetime and the method disclosed by the present invention is capable of extending lifetime of a storage device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of a storage device in accordance with an embodiment of the present invention.

FIG. 2 is a first flowchart showing a method for extending lifetime of a storage device in accordance with the operation schemes of the storage device in the above embodiment of the present invention.

FIG. 3 is a second flowchart showing a method for extending lifetime of a storage device in accordance with the operation schemes of the storage device in the above embodiment of the present invention.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ”. The terms “couple” and “coupled” are intended to mean either an indirect or a direct electrical connection. Thus, if a first device couples to a second device, that connection may be through a direct electrical connection, or through an indirect electrical connection via other devices and connections.

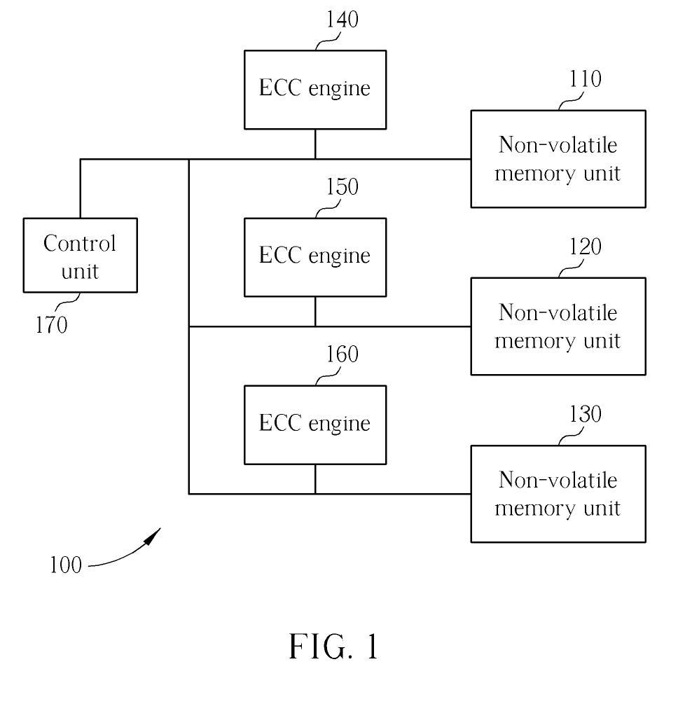

Please refer to FIG. 1. FIG. 1 shows a simplified block diagram of a storage device 100 in accordance with an embodiment of the present invention. As shown in FIG. 1, the storage device 100 comprises: three non-volatile memory units 110, 120, 130, three error correction code (ECC) engines 140, 150, 160, and a control unit 170. The non-volatile memory units 110, 120, 130 all comprise a plurality of blocks (not shown), and the blocks comprising a plurality of pages (not shown), respectively. The ECC engines 140, 150, 160 are respectively coupled to the non-volatile memory units 110, 120, 130, and utilized for detecting and correcting errors for the non-volatile memory units 110, 120, 130. The control unit 170 is coupled to the non-volatile memory units 110, 120, 130, and the ECC engine 140, 150, 160, and utilized for selectively labeling a specific block in a corresponding non-volatile memory unit as an abnormal block according to an error detecting result of each ECC engine. Please note that the storage device 100 can be a solid state drive (SSD), and the non-volatile memory units 110, 120, 130 can be NAND type flash memories, and the control unit 170 can be a CPU.

For example, when a page of the specific block in the non-volatile memory unit 110 has page program fail, the ECC engine 140 will check an error bit number of the page to generate the error detecting result, and the control unit 170 will compare the error bit number of the page with a predetermined threshold value, and when the error bit number of the page is greater than the predetermined threshold value, the control unit 170 will label the specific block as an abnormal block, and when the error bit number of the page is not greater than the predetermined threshold value, the control unit 170 will not label the specific block as an abnormal block. The predetermined threshold value is greater than 0 and smaller than a largest bit number that the ECC engine 140 can correct.

In addition, in another condition, when the specific block in the non-volatile memory unit 120 has block erase fail, the ECC engine 150 will check error bit numbers of a plurality of pages in the specific block one by one to generate the error detecting result, and the control unit 170 will compare the error bit number of each checked page in the specific block with a predetermined threshold value, and when the error bit number of at least a page in the specific block is greater than the predetermined threshold value, the control unit 170 will label the specific block as an abnormal block, and when the error bit numbers of all the page in the specific block are not greater than the predetermined threshold value, the control unit 170 will not label the specific block as an abnormal block. The predetermined threshold value is greater than 0 and smaller than a largest bit number that the ECC engine 150 can correct.

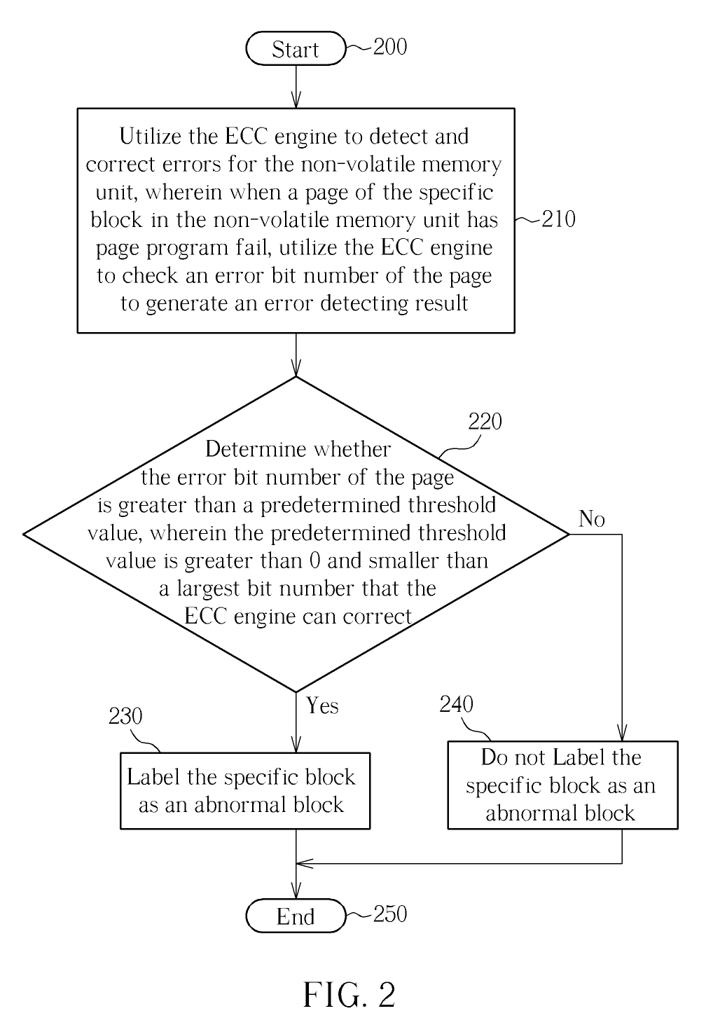

Please refer to FIG. 2. FIG. 2 is a first flowchart showing a method for extending lifetime of a storage device in accordance with the operation schemes of the storage device 100 in the above embodiment of the present invention, wherein the storage device comprises at least a non-volatile memory unit and at least an ECC engine, and the non-volatile memory unit comprises a plurality of blocks, and the blocks respectively comprise a plurality of pages. Provided that substantially the same result is achieved, the steps of the process flowchart need not be in the exact order shown in FIG. 2 and need not be contiguous, that is, other steps can be intermediate. The method in accordance with the first embodiment of the present invention comprises the following steps:

Step 200: Start.

Step 210: Utilize the ECC engine to detect and correct errors for the non-volatile memory unit, wherein when a page of the specific block in the non-volatile memory unit has page program fail, utilize the ECC engine to check an error bit number of the page to generate an error detecting result.

Step 220: Compare the error bit number of the page with a predetermined threshold value, wherein the predetermined threshold value is greater than 0 and smaller than a largest bit number that the ECC engine can correct; when the error bit number of the page is greater than the predetermined threshold value, go to Step 230; and when the error bit number of the page is not greater than the predetermined threshold value, go to Step 240.

Step 230: Label the specific block as an abnormal block

Step 240: Do not Label the specific block as an abnormal block.

Step 250: End.

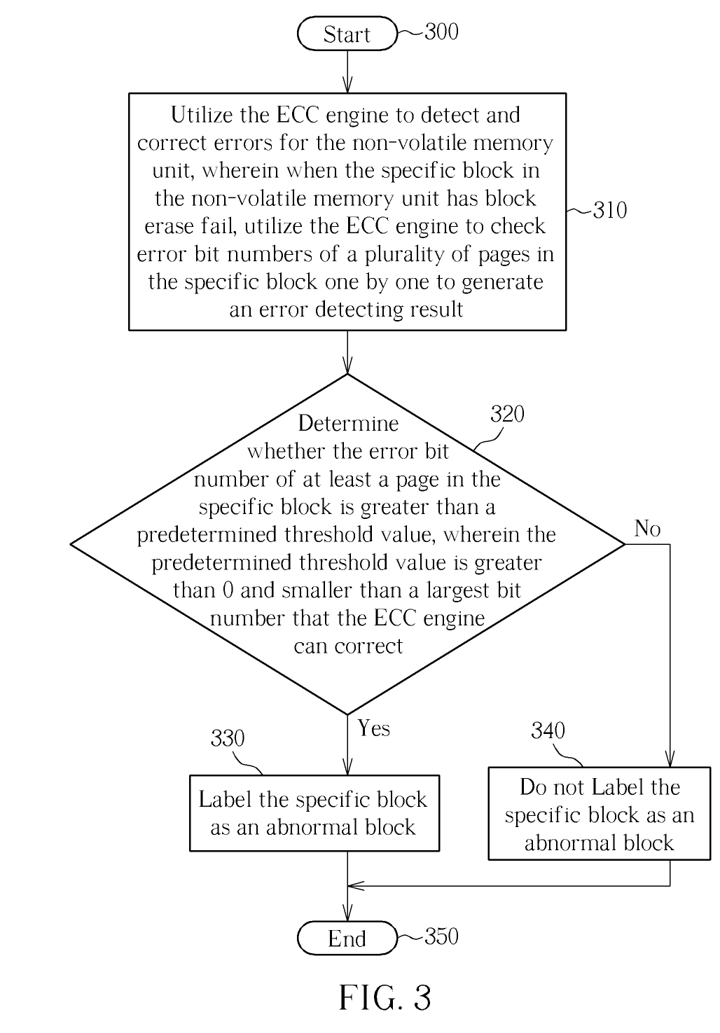

Please refer to FIG. 3. FIG. 3 is a second flowchart showing a method for extending lifetime of a storage device in accordance with the operation schemes of the storage device 100 in the above embodiment of the present invention, wherein the storage device comprises at least a non-volatile memory unit and at least an ECC engine, and the non-volatile memory unit comprises a plurality of blocks, and the blocks respectively comprise a plurality of pages. Provided that substantially the same result is achieved, the steps of the process flowchart need not be in the exact order shown in FIG. 3 and need not be contiguous, that is, other steps can be intermediate. The method in accordance with the second embodiment of the present invention comprises the following steps:

Step 300: Start.

Step 310: Utilize the ECC engine to detect and correct errors for the non-volatile memory unit, wherein when the specific block in the non-volatile memory unit has block erase fail, utilize the ECC engine to check error bit numbers of a plurality of pages in the specific block one by one to generate an error detecting result.

Step 320: Compare the error bit number of each checked page in the specific block with a predetermined threshold value, wherein the predetermined threshold value is greater than 0 and smaller than a largest bit number that the ECC engine can correct; when the error bit number of at least a page in the specific block is greater than the predetermined threshold value, go to Step 330; and when the error bit numbers of all the page in the specific block are not greater than the predetermined threshold value, go to Step 340.

Step 330: Label the specific block as an abnormal block

Step 340: Do not Label the specific block as an abnormal block.

Step 350: End.

Briefly summarized, with regard to the conventional storage device having at least a NAND type flash memory, when a block in the NAND memory unit has page program fail or block erase fail, the conventional storage device will label the block as an abnormal block without a further check. However, the storage device and related method disclosed by the present invention are not like the conventional storage device and related method, and thus the storage device disclosed by the present invention is capable of extending lifetime and the method disclosed by the present invention is capable of extending lifetime of a storage device.

Those skilled in the art will readily observe that numerous modifications and alterations of the device and method may be made while retaining the teachings of the invention.

What is claimed is:

1. A storage device, comprising:
at least a non-volatile memory unit, the non-volatile memory unit comprising a plurality of blocks, and the blocks comprising a plurality of pages, respectively;
at least an error correction code (ECC) engine, coupled to the non-volatile memory unit, for detecting and correcting errors for the non-volatile memory unit; and
a control unit, coupled to the non-volatile memory unit and the ECC engine, for selectively labeling a specific block in the non-volatile memory unit as an abnormal block according to an error detecting result of the ECC engine.

2. The storage device of claim 1, wherein when a page of the specific block in the non-volatile memory unit has page program fail, the ECC engine checks an error bit number of the page to generate the error detecting result, and the control unit compares the error bit number of the page with a predetermined threshold value, and when the error bit number of the page is greater than the predetermined threshold value, the control unit labels the specific block as an abnormal block, and when the error bit number of the page is not greater than the predetermined threshold value, the control unit does not label the specific block as an abnormal block.

3. The storage device of claim 2, wherein the predetermined threshold value is greater than 0 and smaller than a largest bit number that the ECC engine can correct.

4. The storage device of claim 1, wherein when the specific block in the non-volatile memory unit has block erase fail, the ECC engine checks error bit numbers of a plurality of pages in the specific block one by one to generate the error detecting result, and the control unit compares the error bit number of each checked page in the specific block with a predetermined threshold value, and when the error bit number of at least a page in the specific block is greater than the predetermined threshold value, the control unit labels the specific block as an abnormal block, and when the error bit numbers of all the page in the specific block are not greater than the predetermined threshold value, the control unit does not label the specific block as an abnormal block.

5. The storage device of claim 4, wherein the predetermined threshold value is greater than 0 and smaller than a largest bit number that the ECC engine can correct.

6. The storage device of claim 1, wherein the non-volatile memory unit is a NAND type flash memory.

7. The storage device of claim 1, wherein the control unit is a CPU.

8. The storage device of claim 1, being a solid state drive (SSD), wherein the SSD comprises a plurality of non-volatile memory units and a plurality of ECC engines; the plurality of ECC engines are respectively coupled to the plurality of non-volatile memory units, for respectively detecting and correcting errors for the plurality of non-volatile memory units; and the control unit selectively labels a specific block in a corresponding non-volatile memory unit as an abnormal block according to an error detecting result of each ECC engine.

9. A method for extending lifetime of a storage device, the storage device comprising at least a non-volatile memory unit and at least an ECC engine, the non-volatile memory unit comprising a plurality of blocks, and the blocks respectively comprising a plurality of pages, the method comprising:
utilizing the ECC engine to detect and correct errors for the non-volatile memory unit; and
selectively labeling a specific block in the non-volatile memory unit as an abnormal block according to an error detecting result of the ECC engine.

10. The method of claim 9, wherein when a page of the specific block in the non-volatile memory unit has page program fail, the step of utilizing the ECC engine to detect and correct errors for the non-volatile memory unit comprises:
utilizing the ECC engine to check an error bit number of the page to generate the error detecting result.

11. The method of claim 10, wherein the step of selectively labeling a specific block in the non-volatile memory unit as an abnormal block according to the error detecting result of the ECC engine comprises:
comparing the error bit number of the page with a predetermined threshold value;
when the error bit number of the page is greater than the predetermined threshold value, labeling the specific block as an abnormal block; and
when the error bit number of the page is not greater than the predetermined threshold value, not labeling the specific block as an abnormal block.

12. The method of claim 11, wherein the predetermined threshold value is greater than 0 and smaller than a largest bit number that the ECC engine can correct.

13. The method of claim 9, wherein when the specific block in the non-volatile memory unit has block erase fail, the step of utilizing the ECC engine to detect and correct errors for the non-volatile memory unit comprises:
utilizing the ECC engine to check error bit numbers of a plurality of pages in the specific block one by one to generate the error detecting result.

14. The method of claim 13, wherein the step of selectively labeling a specific block in the non-volatile memory unit as an abnormal block according to the error detecting result of the ECC engine comprises:
comparing the error bit number of each checked page in the specific block with a predetermined threshold value;
when the error bit number of at least a page in the specific block is greater than the predetermined threshold value, labeling the specific block as an abnormal block; and
when the error bit numbers of all the page in the specific block are not greater than the predetermined threshold value, not labeling the specific block as an abnormal block.

15. The method of claim 14, wherein the predetermined threshold value is greater than 0 and smaller than a largest bit number that the ECC engine can correct.

16. The method of claim 9, wherein the non-volatile memory unit is a NAND type flash memory.

17. The method storage device of claim 4, wherein the storage device is a solid state drive (SSD), and the SSD comprises a plurality of non-volatile memory units and a plurality of ECC engines; the plurality of ECC engines are respectively coupled to the plurality of non-volatile memory units, for respectively detecting and correcting errors for the plurality of non-volatile memory units; and the control unit selectively labels a specific block in a corresponding non-volatile memory unit as an abnormal block according to an error detecting result of each ECC engine.
